(19) United States
(12) Patent Application Publication
(10) Pub. No.: US 2021/0033975 A1
(43) Pub. Date: Feb. 4, 2021

(54) PERMANENT BONDING AND PATTERNING MATERIAL

(71) Applicant: Brewer Science, Inc., Rolla, MO (US)

(72) Inventors: Reihaneh Sejoubsari, Greenvale, NY (US); Tony D. Flaim, St. James, MO (US); Xiao Liu, Rolla, MO (US)

(21) Appl. No.: 16/945,542

(22) Filed: Jul. 31, 2020

Related U.S. Application Data
(60) Provisional application No. 62/881,970, filed on Aug. 2, 2019.

(51) Int. Cl. G03F 7/11; G03F 7/34; G03F 7/004; C08L 33/14; B81C 1/00

(52) U.S. Cl. CPC G03F 7/11; G03F 7/34; B81C 1/00269; C08L 33/14; G03F 7/0045

(57) ABSTRACT

Methods are disclosed to prepare permanent materials that can be coated onto microelectronic substrates or used for other structural or optical applications. The materials are thermally stable to at least about 300° C., curable using a photo or thermal process, exhibit good chemical resistance (including during metal passivation), and have a lifespan of at least about 5 years, preferably at least about 10 years, in the final device. Advantageously, these materials can also be bonded at room temperature. The materials exhibit no movement or squeeze-out after bonding and adhere to a variety of substrate types.

### RELATED APPLICATIONS

The present application claims the priority benefit of U.S. Provisional Patent Application Ser. No. 62/881,970, filed Aug. 2, 2019, entitled PERMANENT BONDING AND PATTERNING MATERIAL, incorporated by reference in its entirety herein.

### BACKGROUND OF THE INVENTION

### Field of the Invention

This invention pertains to permanent materials useful for bonding or coating of semiconductor substrates.

### Description of Related Art

Permanent bonding adhesive materials can be used for a number of technology areas, including CMOS image sensors, 3D IC applications, MEMS, and wafer- and panel-level packaging (WLP and PLP, respectively).

Currently available permanent bonding materials for these applications have limitations, including limited long-term stability, limited temperature stability (below glass transition temperature), and lower bonding strengths. There are concerns over epoxy resins derived from bisphenol A or cresol. Many customers cannot use materials that contain antimony or other heavy metals, which precludes antimony-containing photoacid generators. Additionally, bisphenol A use may be limited due to health and environmental concerns. Similarly, some applications cannot use silicone-containing materials. Benzocyclobutene (“BCB”), a widely used bonding adhesive in these applications, has challenges in achieving void-free adhesive bonding with simultaneous high post-bonding alignment accuracy.

Thus, there is a need for bonding compositions that are suitable for both temporary and permanent bonding applications as well as for photopatterning and laser patterning processes.

### SUMMARY OF THE INVENTION

The present invention is broadly concerned with methods of forming a microelectronic structure, compositions used in those methods, and the structures resulting from those methods.

In one embodiment, the invention provides a method that comprises providing a substrate having a back surface and a front surface, applying a composition to the front surface to form a bonding layer, and attaching a die to the bonding layer. The composition is chosen from:
(I) a composition comprising less than about 0.001% by weight of an initiator, based upon the total weight of the composition taken as 100% by weight, where the composition also comprises a compound including a moiety having the structure:

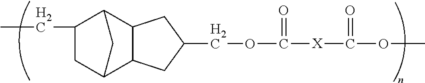

where: each X is independently chosen from substituted or unsubstituted aliphatics, aryls, and heterocyclics; and n is 1 to about 20; or
(II) a composition comprising a dye and a compound including a moiety having the structure:

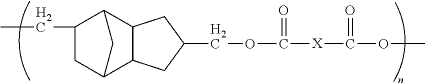

where: each X is independently chosen from substituted or unsubstituted aliphatics, aryls, and heterocyclics; and n is 1 to about 20.

In another embodiment, the invention provides a method that comprises providing a substrate having a back surface and a front surface, the substrate optionally includes one or more intermediate layers on the front surface. A composition is applied to the front surface, or to the one or more intermediate layers, if present, to form a bonding layer. The composition comprises a compound including a moiety having the structure:

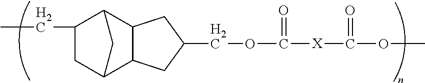

where: each X is independently chosen from substituted or unsubstituted aliphatics, aryls, and heterocyclics; and n is 1 to about 20. A patterned bonding layer is formed by doing one or both of (A) or (B):
(A) forming a photoresist layer on the bonding layer;
   forming a pattern in the photoresist layer; and
   transferring the pattern to the bonding layer to form a patterned bonding layer; or
(B) exposing the bonding layer to laser energy so as to remove at least a portion of the bonding layer.

In yet a further embodiment, the invention provides a temporary bonding method comprising providing a stack that comprises a first substrate having a back surface and a front surface. The substrate optionally includes one or more intermediate layers on its front surface. The stack also comprises a bonding layer on the front surface, or on the one or more intermediate layers, if present, and a second substrate having a first surface. The bonding layer is on the first surface and formed from a composition comprising a dye and a compound including a moiety having the structure:

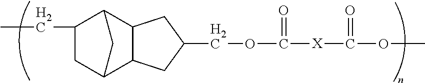

where: each X is independently chosen from substituted or unsubstituted aliphatics, aryls, and heterocyclics; and n is 1 to about 20. The bonding layer is exposed to laser energy so as to facilitate separation of the first and second substrates.

In yet a further embodiment, the invention provides a composition comprising a compound dispersed or dissolved in a solvent system. The compound includes a moiety having the structure:

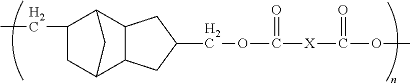

where: each X is independently chosen from substituted or unsubstituted aliphatics, aryls, and heterocyclics; and n is 1 to about 20. The composition further comprises one or both of the following:
(a) a dye; or
(b) less than about 0.001% by weight of an initiator, based on the total weight of the composition being taken as 100% by weight.

In another embodiment, the invention provides a microelectronic structure comprising a substrate having a back surface and a front surface. A bonding layer is on the front surface, and the bonding layer is chosen from:
(I) a bonding layer comprising less than about 0.001% by weight of an initiator, based upon the total weight of the bonding layer taken as 100% by weight, and a crosslinked moiety of:

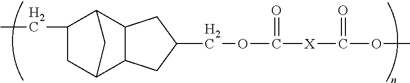

where: each X is independently chosen from substituted or unsubstituted aliphatics, aryls, and heterocyclics; and n is 1 to about 20; or
(II) a bonding layer comprising a dye and a crosslinked moiety of:

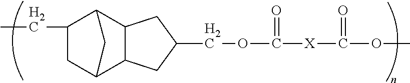

where: each X is independently chosen from substituted or unsubstituted aliphatics, aryls, and heterocyclics; and n is 1 to about 20.

### BRIEF DESCRIPTION OF THE DRAWINGS

FIG. 1 is a schematic depiction (not to scale) of a die-attaching process according to one embodiment of the invention;

FIG. 2 is a schematic drawing (not to scale) of a process according to another embodiment of the invention where the bonding layer is patterned by dry etching, using a patterned photoresist as an etch mask;

FIG. 3 is a cross-sectional view of a schematic drawing of a temporary bonding process according to one embodiment of the invention;

FIG. 4 is a schematic drawing depicting a laser patterning process according to another embodiment of the invention; and

FIG. 5 is an image of a coated silicon wafer (left) and of a bonded wafer pair (right) formed as described in Example 9.

### DETAILED DESCRIPTION

The present invention is concerned with compositions and methods of using those compositions for die-attach processes and other permanent bonding processes, for forming patterned layers, and/or for temporary wafer bonding.

### Compositions

The inventive compositions are formed by mixing a compound and any optional ingredients in a solvent system.

### 1. Preferred Compounds

Preferred compounds can be polymeric, oligomeric, monomeric, or even a mixture thereof, and preferably comprise a polyester, acrylate, methacrylate, or mixture thereof.

One preferred compound includes a moiety having the structure (I):

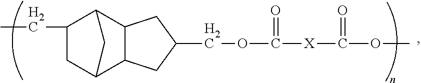

wherein each X is independently chosen from substituted or unsubstituted aliphatics, aryls, and heterocyclics; and n is 1 to about 20, preferably from 1 to about 10, and even more preferably from 1 to about 5.

As used herein, “aliphatics” includes alkyl, alkenyl, and cycloalkyl moieties. Preferred alkyls can be straight-chained or branched and are C₁ to about C₅₀, more preferably C₁ to about C₄₀, and even more preferably from about C₂₀ to about C₄₀ alkyls. Preferred alkenyls can also be straight-chained or branched and are C₂ to about C₅₀, more preferably C₂ to about C₄₀, and even more preferably from about C₂₀ to about C₄₀ alkenyls. Preferred cycloalkyls are C₅ to about C₂₀, and more preferably C₅ to about C₁₂ cycloalkyls.

“Aryls” preferably refers to C₆ to about C₂₆, more preferably C₆ to about C₂₀, and even more preferably from C₆ to about C₁₄ aryls.

“Heterocyclic” refers to ring-containing groups containing one or more heteroatoms (e.g., N, O, S) as part of the ring structure, with heteroaryl moieties being included in this definition. Preferred heterocyclics are C₃ to about C₂₆, and more preferably from C₃ to about C₂₀.

With any of the foregoing aliphatics, aryls, or heterocyclics, “substituted” refers to any of the foregoing moieties where one or more atoms that are part of the main chain or ring have substituent atoms or groups such as one or more of the following: alkyl, halogen, cyano, nitro, amino, amido, sulfonyl, hydroxy, etc.

Particularly preferred X groups for structure (I) above are independently chosen from one or more of the following:

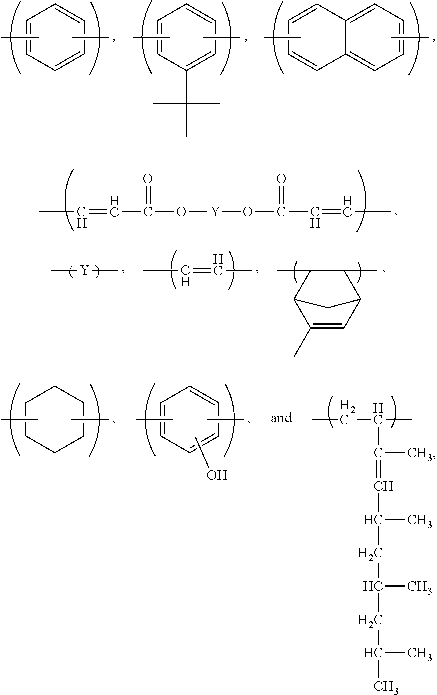

where Y is C₁ to about C₄₅, preferably from C₁ to about C₃₀, and more preferably from C₁ to C₁₀. In one embodiment, Y is C₃₆, which preferably includes a mixture of isomeric C₃₆ branched and cyclic hydrocarbon moieties. In another embodiment, Y is an alkyl or alkenyl with the foregoing carbon atom ranges.

In a particularly preferred embodiment, the compound comprises structure (I) above and further comprises at least one of the following structures bonded with structure (I):

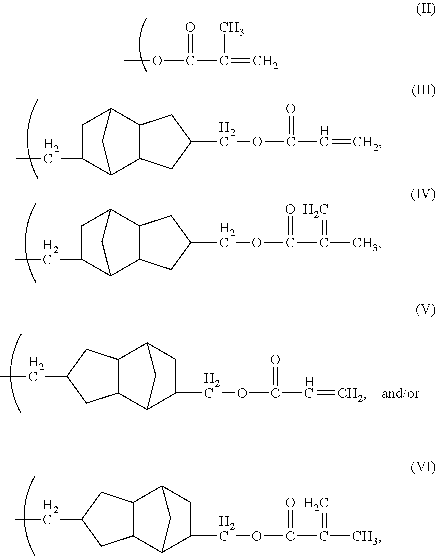

In a particularly preferred embodiment, structure (I) is bonded with structure (II) above and one of structures (III)-(VI). In the most preferred embodiment, the compound has the structure:

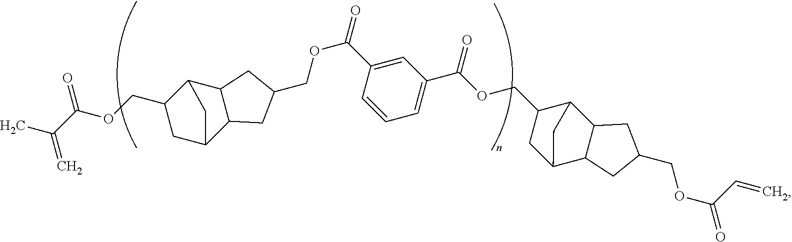

which is structure (I) bonded with structure (II) and structure (III). This polymer is commercially available under the name PEAM-645 from Designer Molecules (San Diego, Calif.). Other polymers according to the disclosure herein can be purchased commercially or can be prepared using known organic chemistry techniques (e.g., transesterification).

Regardless of the chosen compound, that compound(s) is preferably present in the inventive composition at levels of from about 40% by weight to about 80% by weight, and more preferably from about 50% to about 70% by weight, based upon the total weight of the composition taken as 100% by weight.

### 2. Solvent

Suitable solvent systems include a single solvent or solvent mixture. Exemplary solvents include, but are not limited to, ethyl lactate, cyclopentanone, cyclohexanone, propylene glycol methyl ether acetate (PGMEA), propylene glycol methyl ether (PGME), mesitylene, and mixtures thereof. The solvent system is present in the material from about 20% by weight to about 60% by weight, and preferably from about 30% by weight to about 50% by weight, based upon the total weight of the composition taken as 100% by weight, with the balance of those percentages being taken up by the solids in the composition. It will be appreciated that the amount of solvent or solvents added to the composition may be different depending on the deposition method utilized.

### 3. Additives

Optionally, additives may be included in the composition. Examples of potential additives include, but are not limited to, crosslinking agents, initiators, surfactants, wetting agents, adhesion promoters, dyes, colorants and pigments, and/or other polymers and resins. These additives would be selected depending on the desired properties and use of the final composition.

Dyes may be added to the material to achieve appropriate optical properties for applications such as laser ablation. When used, suitable dyes include, but are not limited to, bis(benzylidene malononitrile), trimethylolpropane triglycidyl ether-4-methoxybenzylidene pyruvic acid, and mixtures thereof. When a dye is included, it is present in the material from about 3% by weight to about 30% by weight, preferably from about 5% to about 10% by weight, based upon the total weight of the composition taken as 100% by weight. The dye can be mixed into the composition, or it can be attached to the compound.

Suitable initiators include, but are not limited to, 9,10-phenanthrenequinone, 4,4′-bis(diethylamino)benzophenone, 2-hydroxy-2-methyl propiophenone (sold under the name DAROCUR® 1173 by Ciba), dicumyl peroxide, benzoyl peroxide, and mixtures thereof. When a photoinitiator is used, it is present in the material at a level of at least about 0.1% by weight, preferably from about 0.1% by weight to about 2% by weight, and more preferably from about 0.3% to about 1% by weight, based upon the total weight of the composition taken as 100% by weight.

Suitable surfactants include, but are not limited to, nonionic fluorinated surfactants, such as MEGAFACE R-30N (DIC Corporation) and F-556 (DIC Corporation), and mixtures thereof. When used, the surfactant is present in the material from about 0.01% by weight to about 0.5% by weight, and preferably from about 0.01% to about 0.2% by weight, based upon the total weight of the composition taken as 100% by weight.

Suitable adhesion promoters include, but are not limited to, methacryloxypropyltrimethoxysilane, 3-glycidyloxypropyltrimethoxysilane, pyromellitic dimethacrylate, pyromellitic dianhydride glycerol dimethacrylate, 4-methacryloxyethyl trimellitic, and mixtures thereof. When used, the adhesion promoter is present in the composition from about 0.01% by weight to about 1% by weight, and preferably from about 0.05% to about 0.5% by weight, based upon the total weight of the composition taken as 100% by weight.

The compositions are made by simply dispersing or dissolving the compound and any additives in a solvent system. While the composition can include one or more additives, in one embodiment, the composition comprises less than about 0.001% by weight initiator, and preferably about 0% by weight initiator, based upon the total weight of the composition taken as 100% by weight. In another embodiment, the composition includes the compound and at least the dye dissolved or dispersed in the solvent system, either with an initiator or with little to no initiator (i.e., less than about 0.001% by weight or about 0% by weight initiator).

In another embodiment, the composition consists essentially of, or even consists of, the compound dispersed or dissolved in the solvent system. In a further embodiment, the composition consists essentially of, or even consists of, the compound and dye dispersed or dissolved in the solvent system. In yet another embodiment, the composition consists essentially of, or even consists of, the compound, an initiator, and dye dispersed or dissolved in the solvent system.

Regardless of the embodiment, the resulting composition is stable at room temperature and can be coated easily onto microelectronic substrates. As used herein, “stable” means that the composition can be stored for periods of at least about 180 days and preferably from about 360 days to about 720 days with less than about 0.1% of precipitation or separation of the solids from the solution.

### Methods of Use

Advantageously, the disclosed compositions are suitable for use in microelectronic structures, optical applications, and structural applications, including as a permanent layer or component in the particular structure or device.

Methods of using the composition involve applying the composition to a substrate to form a layer of the composition thereon. The substrate can be any microelectronic substrate. In embodiments where the substrate is a device substrate, the substrate utilized will preferably include topography (e.g., contact holes, via holes, raised features, and trenches). This topography can be included directly on the substrate surface, or it can be included in one or more layers of other material formed on the substrate surface. Preferred substrates include those commonly used in front-end and back-end applications. When the substrate is a carrier substrate, the substrate utilized will not include topography. Particularly preferred substrates are chosen from silicon, aluminum, tungsten, tungsten silicide, gallium arsenide, germanium, tantalum, tantalum nitrite, silicon germanium, glass, copper, chrome, zinc, silicon oxide, silicon nitride (SiN), and combinations thereof.

The compositions can be coated onto the substrate by spin coating, slot-die coating, ink jet printing and other methods compatible with the application of solvent-based coating formulations. These techniques may require the adjustment of the polymer solids level in the solution to obtain the desired coating thickness and uniformity without defects, for example, by diluting the solution with the principal solvent and/or adding co-solvents that do not cause polymer precipitation. A preferred method of application is spin coating at speeds from about 800 rpm to about 2,500 rpm, and more preferably from about 1,000 rpm to about 1,500 rpm for a time period of from about 20 seconds to about 60 seconds, and preferably from about 30 seconds to about 40 seconds.

After application to the substrate, the composition is solvent baked to evaporate any residual solvent. The solvent bake temperature should be from about 60° C. to about 150° C., and preferably from about 60° C. to about 120° C. This heating step is preferably carried out for a time period of from about 1 second to about 6 minutes, and more preferably from about 60 seconds to about 4 minutes. It will be appreciated that the solvent bake may be performed in more than one step, that is, it may be first baked at a lower temperature, followed by a second bake at a higher temperature.

After the solvent bake and any intermediate steps, the composition is preferably cured, either by a thermal or photo process, depending upon whether an initiator was included and, if so, whether it was a thermal initiator or a photoinitiator. In instances where no initiator is included, the layer of composition should be heated to about 140° C. to about 250° C., and more preferably from about 180° C. to about 220° C., typically for about 5 minutes to about 60 minutes, and preferably from about 10 minutes to about 30 minutes. For thermal curing (i.e., a thermal initiator is included in the composition), the composition should be heated to above its crosslinking temperature, preferably from about 180° C. to about 250° C., and more preferably from about 200° C. to about 250° C. for a time period of from about 10 minutes to about 60 minutes, and preferably from about 10 minutes to about 30 minutes. For photo curing (i.e., a photoinitiator is included in the composition), the composition may be cured by exposure to radiation, such as UV or visible radiation. Exposure wavelengths vary based on chemistry, but are preferably from about 200 nm to about 500 nm, and more preferably from about 300 nm to about 400 nm, for a time period of from about 60 seconds to about 15 minutes, and preferably from about 60 seconds to about 5 minutes. The exposure dose varies based on the chemistry but is preferably from about 3 mJ/cm² to about 50 mJ/cm², and more preferably from about 10 mJ/cm² to about 30 mJ/cm².

The coatings preferably have a thickness (average measurements taken over five locations by an ellipsometer) of between about 1 μm and about 20 μm, and more preferably about 3 μm to about 10 μm. Advantageously, a coating thickness of about 5 μm has relatively low curing stress, which prevents substrate bowing, and thus makes the wafer/substrate processable in post-coating processes.

Additionally, because the materials have the property of crosslinking in response to UV radiation, this allows the materials to be molded, cast into form, etc., by thermoplastic processing and then hardening by UV exposure, thus forming a free-standing film or laminate that can be adhered to a substrate at the time of use. Alternately, areas within the film can be selectively hardened by patterned exposure, for example, to create regions that are stiffer or more thermally stable. Regardless of whether crosslinking is allowed to happen over time or is caused to happen via thermal or photocuring, bridges will form between the above-described compounds, causing the material to go from thermoplastic in nature to thermoset. Specifically, acrylate and/or methacrylate groups in the polymer crosslink by radical polymerization to form a crosslinked polymer structure.

Advantageously, these materials may be used for a variety of semiconductor packaging processes. Depending on the process, intermediate steps may be performed between the initial coating and solvent bake of the material before curing. Exemplary process flows utilizing these materials in conjunction with the above conditions (unless stated otherwise) are described below.

### 1. Die Attach Process

Referring to FIG. 1, a substrate 10 is provided, with the substrate 10 having a front surface 12 and a back surface 14. Substrate 10 can be any of the substrates described above. A layer 16 of a composition as described above is applied to front surface 12 and solvent baked, as described above. Layer 16 has an upper surface 18 and a lower surface 20, with its lower surface 20 being in contact with front surface 12 of substrate 10. Next, dies 22 are attached to upper surface 18 of layer 16, and the composition is cured. Curing will take place over time or can be effected by thermal curing or photocuring, depending upon whether an initiator is utilized and, if so, the type of initiator. Regardless, the dies 22 are now attached to permanent bonding layer 16. Next, vias 24 can be drilled (e.g., by laser drilling) through the substrate 10 from the direction of back surface 14. A metal layer 26 is then deposited into vias 24 and on back surface 14 following conventional metallization processes and further processing steps (e.g., passivation, patterning, redistribution layer (“RDL”) formation, singulation, electroplating, plasma etching, cleaning, chemical vapor deposition, physical vapor deposition, and combinations of the foregoing) can then be carried out, depending upon the particular application and end user goals.

### 2. Photopatterning Process

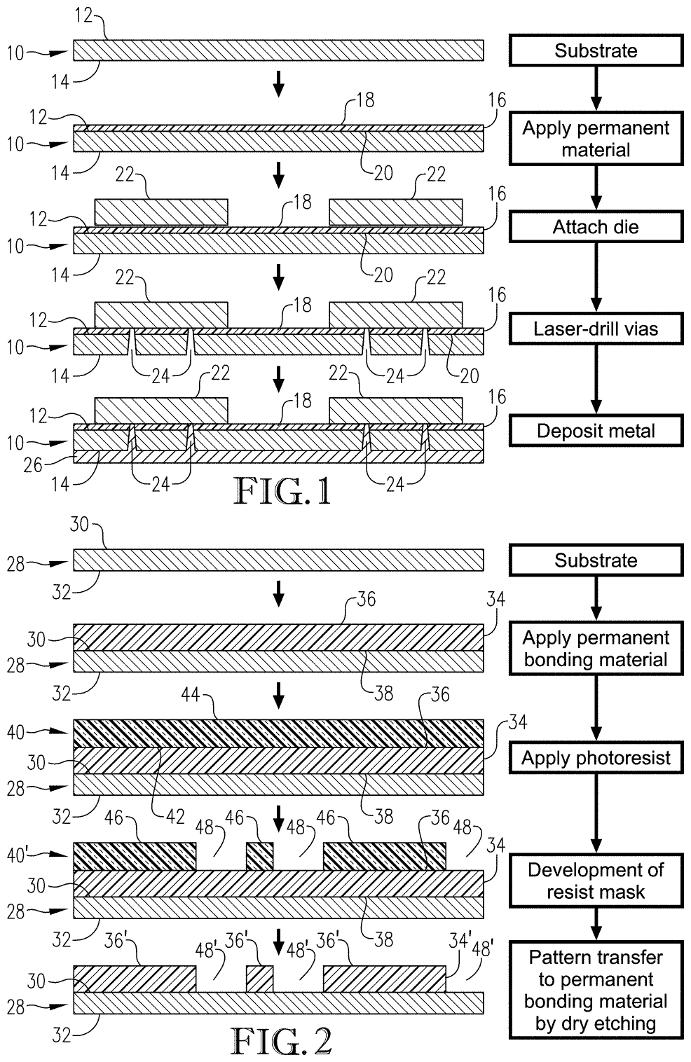

Referring to FIG. 2, a substrate 28 is provided, with the substrate 28 having a front surface 30 and a back surface 32. Substrate 28 can be any of the substrates described above. A layer 34 of a composition as described above is applied to front surface 30 and solvent baked, as described above. Layer 34 has an upper surface 36 and a lower surface 38, with its lower surface 38 being in contact with front surface 30 of substrate 28. After solvent baking, the layer 34 is cured or allowed to cure, as described above.

Next, a conventional photoresist composition is applied (following conventional processes) to upper surface 36 of layer 34, so as to form photosensitive layer 40 having lower surface 42 and upper surface 44, with lower surface 42 being in contact with upper surface 36 of layer 34 (i.e., of the layer formed from a composition according to the inventive embodiments described herein). The photoresist layer 40 is dried or baked, per the manufacturer's instructions. The photoresist layer 40 is then exposed to UV light through a mask (not shown) having the desired pattern. One of ordinary skill in the art will understand how to form the pattern, including taking into account whether the photoresist is positive-acting or negative acting. Additionally, the exposure wavelength, dose, etc., can be determined by the skilled artisan based on the photoresist's chemistry and/or manufacturer's recommendations. After exposure and any post-exposure bake, the photoresist layer 40 is developed using an aqueous developer so as to form a patterned photoresist layer 40′. Patterned photoresist layer 40′ has portions 46 remaining after development as well as “voids” 48 that were removed during development. Portions 46 and voids 48 cooperate to form the patterned photoresist layer 40′, which can now be used as an etch mask to dry etch (e.g., using CF₄ etchant) the inventive layer 34, transferring the pattern from patterned photoresist layer 40′ down to the inventive layer 34, thus forming patterned layer 34′ having remaining portions 36′ and “voids” 48′, corresponding to those of patterned photoresist layer 34′. Subsequent processing steps can now be performed using the patterned permanent bonding material. For example, one or more dies (not shown) can be attached to patterned layer 34′. In those instances, the voids 48′ can be used as a template for locations to fix the one or more dies or other structures. Other processing that could be carried out at this stage includes die encapsulation, hermetic sealing, and/or hybrid bonding.

### 3. Bonding Process

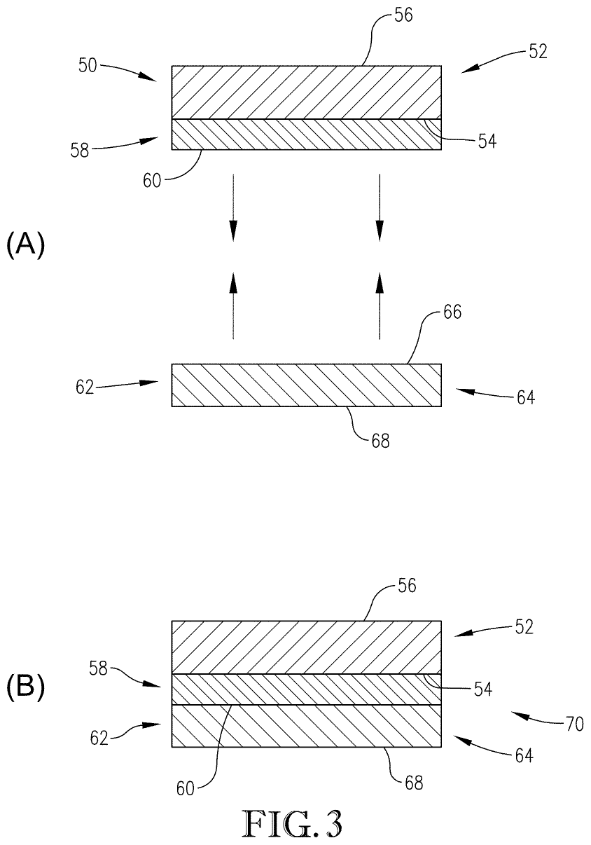

Referring to FIG. 3(A) (not to scale), a precursor structure 50 is depicted in a schematic and cross-sectional view. Structure 50 includes a first substrate 52. Substrate 52 has a front or device surface 54 and a back surface 56. Preferred first substrates 52 include device wafers such as those whose device surfaces comprise arrays of devices (not shown) selected from the group consisting of integrated circuits, MEMS, microsensors, power semiconductors, light-emitting diodes, photonic circuits, interposers, embedded passive devices, and other microdevices fabricated on or from silicon and other semiconducting materials such as silicon-germanium, gallium arsenide, gallium nitride, aluminum gallium arsenide, aluminum indium phosphide, and indium gallium phosphide. The surfaces of these devices commonly comprise structures (again, not shown) formed from one or more of the following materials: silicon, polysilicon, silicon dioxide, silicon (oxy)nitride, metals (e.g., copper, aluminum, gold, tungsten, tantalum), low k dielectrics, polymer dielectrics, and various metal nitrides and silicides. The device surface 54 can also include at least one structure selected from the group consisting of: solder bumps; metal posts; metal pillars; and structures formed from a material selected from the group consisting of silicon, polysilicon, silicon dioxide, silicon (oxy)nitride, metal, low k dielectrics, polymer dielectrics, metal nitrides, and metal silicides.

A composition according to the invention is applied to the first substrate 52 (following the steps described previously) to form a bonding layer 58 on the device surface 54, as shown in FIG. 3(a). Bonding layer 58 has an upper surface 60 remote from first substrate 52. The bonding layer 50 can be formed directly on the device surface 54 (i.e., without any intermediate layers between the bonding layer 58 and substrate 52), or one or more intermediate layers (not shown; e.g., hardmask layer, spin-on carbon layer, dielectric layer, release layer, etc.) could first be formed on device surface 54, and bonding layer 58 can then be formed directly on the uppermost intermediate layer. Regardless, bonding layer 58 is applied and solvent baked following the steps described previously.

A second precursor structure 62 is also depicted in a schematic and cross-sectional view in FIG. 3(a). Second precursor structure 62 includes a second substrate 64. In this embodiment, second substrate 64 is a carrier wafer and has a front or carrier surface 66 and a back surface 68. Although second substrate 64 can be of any shape, it would typically be shaped and sized similarly to first substrate 52. Preferred second substrates 64 include a clear wafer or any other transparent (to laser energy) substrate that will allow the laser energy to pass through the carrier substrate, including, but not limited to, glass, Corning Gorilla glass, and sapphire. One especially preferred glass carrier wafer is a Corning EAGLE XG glass wafer.

After the solvent bake noted above, the two substrates 52 and 64 are bonded together in a face-to-face configuration under pressure, with the permanent bonding material (i.e., the composition described herein) between the two substrates along with any additional intermediate layers, so as to form bonded stack 70 (FIG. 3(B)). Preferred bonding pressures are from about 100 N to about 5,000 N, and more preferably from about 1,000 N to about 3,000 N. Preferred bonding times are from about 30 seconds to about 5 minutes, and more preferably from about 30 seconds to about 2 minutes. Preferred bonding temperatures are from about 20° C. to about 120° C., and more preferably from about 30° C. to about 70° C. In one embodiment, bonding is preferably carried out at room temperature.

The bonding layer 58 adheres to a variety of substrate types and will not exhibit movement or “squeeze-out” after bonding. First substrate 52 can now be safely handled and subjected to further processing that might otherwise have damaged first substrate 52 without being bonded to second substrate 64. For example, the structure can be subjected to backside processing such as back-grinding, chemical-mechanical polishing (“CMP”), etching, metal deposition (i.e., metallization), dielectric deposition, patterning (e.g., photolithography, via etching), passivation, annealing, and combinations thereof, without separation of substrates 52 and 64 occurring, and without infiltration of any chemistries encountered during these subsequent processing steps. In one embodiment, the bonded stack 70 may remain bonded permanently during and after the subsequent processing steps.

In another embodiment, once processing is complete, the substrates 52 and 64 can be separated by using a laser to decompose or ablate all or part of the bonding layer 58. This is particularly useful in embodiments where the composition used to form bonding layer 58 included a dye. Suitable laser wavelengths include from about 200 nm to about 400 nm, and preferably from about 300 nm to about 360 nm. In order to debond the bonding layer 58, a laser is scanned across the surface of the substrate 64 in a stand-and-repeat method or line scan method in order to expose the entire wafer. Exemplary laser debonding tools include the SUSS MicroTec Lambda STEEL 2000 laser debonder and Kingyoup laser debonder. The substrate 64 is preferably scanned by the laser spot with a field size from about 40×40 μm to about 12.5×4 mm. Suitable fluence to debond the substrates 52, 64 is from about 100 mJ/cm² to about 400 mJ/cm², and preferably from about 150 mJ/cm² to about 350 mJ/cm². Suitable power to debond the substrates 52, 64 is from about 0.5 W to about 6 W, and preferably from about 1 W to about 2 W. After laser exposure, the substrates 52 and 64 will readily separate. After separation, any remaining bonding layer 58 can be removed with a plasma etch or a solvent capable of dissolving the bonding layer 58.

Alternatively, debonding can be carried out by mechanically disrupting, cutting, and/or dissolving bonding layer 58.

In the above embodiments, the bonding layer 58 is shown on a first substrate 52 that is a device wafer. It will be appreciated that this substrate/layer scheme could be reversed. That is, the bonding layer 58 could be formed on second substrate 64 (the carrier wafer). The same compositions and processing conditions would apply to this embodiment as those described above.

### 4. Laser Patterning Process

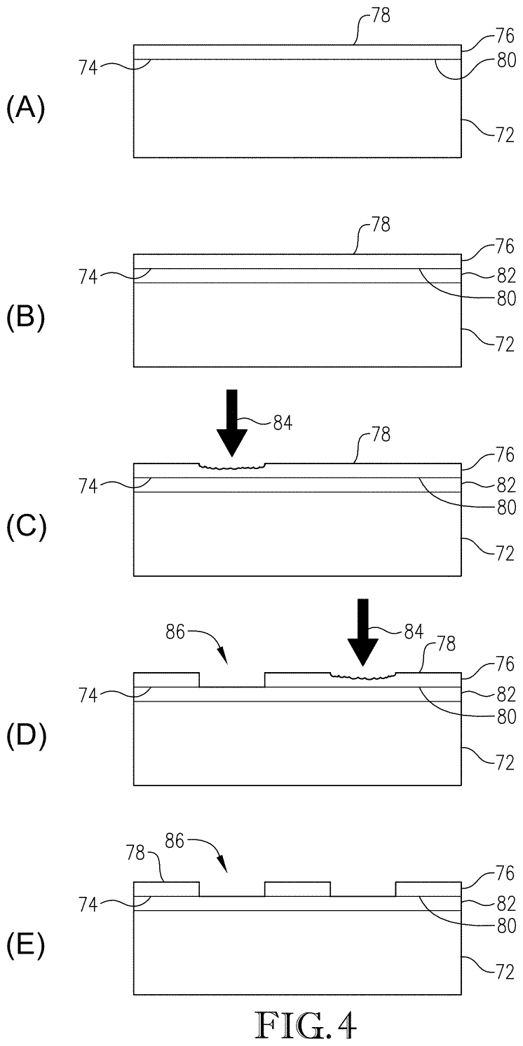

FIGS. 4(A)-4(D) schematically illustrate a further embodiment of the invention where a structure is formed by applying the compositions described herein and subsequently using the formed layer in a laser patterning process. This is particularly useful in embodiments where the composition used to form bonding layer 58 includes a dye.

In this process, a substrate 72 having a surface 74 is provided. Any microelectronic substrate can be used in the invention, including those described previously. The method of applying the composition to form a layer 76, which will function as an insulating dielectric layer, is according to the general method described previously. As with previous embodiments, the substrate 72 can have a planar surface, or it can include topography features. The layer 76 can also be allowed to cure or made to cure as described with previous embodiments.

Final layer 76 has an upper surface 78 and a lower surface 80. Although the foregoing depicts the lower surface 80 of the layer 76 being in direct contact with the substrate surface 74, it will be appreciated that any number of optional intermediate layers 82 may be formed on the substrate surface 74 prior to forming inventive layer 76. These intermediate layers 82 include adhesion promoting layers, metal layers, or both. These optional layers 82 would be formed according to conventional processes, and the layer 76 would be formed on top of the last/uppermost intermediate layer 82 that is utilized, following the process described above, so that the lower surface 80 of layer 76 is in contact with the uppermost intermediate layer 82. This embodiment is depicted in FIG. 4(B).

Regardless of whether intermediate layer(s) 82 are included, the layer 76 is then patterned by laser ablation, preferably using an excimer laser to expose the layer 76 to laser energy. A laser beam 84 is applied in short pulses to the material forming layer 76. The laser may be used in a “direct write” fashion in which a small laser beam is rastered only in the areas to be ablated (FIG. 4(C)), or the laser may be applied through a metal mask (not shown) so as to only ablate the areas where the laser is able to pass through the mask. The laser energy is absorbed by the material of layer 76 and as a result of various photochemical and thermal effects, portions of the layer 76 are removed to create a first opening 86 (FIG. 4(C)). The laser can then be directed to other areas of layer 76 where removal is desired and further ablation can be carried out (FIG. 4(D)) to form a further opening(s) 86 (FIG. 4(E)).

The excimer laser wavelength is preferably from about 200 nm to 450 nm, more preferably from about 250 nm to 400 nm, and even more preferably from about 300 nm to 400 nm. The pulse rate is less than about 4,000 Hz, preferably from about 100 Hz to about 3,500 Hz, more preferably from about 1,000 Hz to about 3,000 Hz, and even more preferably from about 2,000 Hz to about 3,000 Hz. The pulse length can be from about 1 μs to about 100 ps, depending on the type of pulsed laser being used. The amount of material removed is dependent upon the material, laser wavelength, pulse rate, and pulse length.

This selective removal can produce features such as lines of the layer 76 material with spaces between the lines where the material has been removed, or in vias (holes) in the material of layer 76, and it will be appreciated that any pattern could be formed by the laser ablation. When lines and spaces are formed using the laser ablation, the width of the lines and spaces is preferably less than about 200 microns, more preferably from about 1 micron to about 70 microns, and even more preferably from about 20 microns to about to 60 microns. When vias are formed using the laser ablation, the diameter of the vias that are formed is preferably less than about 700 microns, more preferably from about 1 micron to about 500 microns, and even more preferably from about 10 microns to about 300 microns. Advantageously, the sidewalls of the features may be substantially perpendicular to the surface of the substrate, that is, the sidewalls of the features make an angle of preferably from about 70° to about 110° with the surface 74 of the substrate 72 (or of the surface of uppermost of any intermediate layers 82 that are present), and more preferably an angle of about 90° with the surface 74 of the substrate 72.

### Layer Properties

Regardless of the embodiment, the cured layers formed by the compositions described herein will have excellent thermal and adhesive properties. Materials preferably have a glass transition temperature (T_{g}) of about 30° C. to about 200° C., and more preferably from about 150° C. to about 200° C. The layers will also preferably have high thermal stabilities, with a decomposition temperature (T_{d}) of at least about 300° C., more preferably at least about 330° C., and even more preferably at least about 390° C. Furthermore, these materials preferably have a CTE (coefficient of thermal expansion) of from about 45 ppm/° C. to about 120 ppm/° C.

The cured layers preferably have a tensile elongation of at least about 4%, and more preferably about 50%, and also exhibit low moisture absorption. The layers are capable of adhering well to materials such as copper, chrome, zinc, aluminum, silicon oxide, silicon nitride (SiN), having adhesion of at least about 10 psi, preferably at least about 30 psi, and even more preferably at least about 40 psi when measured by ASTM D4541-17.

The cured materials can also serve as a dielectric material. In such instances, they will have a dielectric constant of at least about 2.0, and preferably at least about 2.7, with a dielectric loss of from about 0.002 to about 0.01, and preferably from about 0.002 to about 0.008. When used in laser ablation applications as described above, the cured layers preferably have a k value of at least about 0.1, and more preferably at least about 0.15. The cured materials will also exhibit good chemical resistance (including during metal passivation), where good chemical resistance is tested by soaking the material in the chemical of interest (e.g., tetramethyl ammonium hydroxide (TMAH), PGME, PGMEA, ethyl lactate, cyclopentanone, cyclohexanone) at a temperature of from about room temperature to about 90° C. for a time period of from about 10 minutes to about 30 minutes. Good chemical resistance is demonstrated when the cured material shows no signs of chemical attack upon visual inspection, and there is little or no thickness loss, that is, preferably less than 10% thickness loss, and more preferably less than about 5% thickness loss. The cured materials will preferably have a lifespan of at least 5 years, and more preferably at least 10 years, in the final device.

Additional advantages of the various embodiments of the invention will be apparent to those skilled in the art upon review of the disclosure herein and the working examples below. It will be appreciated that the various embodiments described herein are not necessarily mutually exclusive unless otherwise indicated herein. For example, a feature described or depicted in one embodiment may also be included in other embodiments but is not necessarily included. Thus, the present invention encompasses a variety of combinations and/or integrations of the specific embodiments described herein.

As used herein, the phrase “and/or,” when used in a list of two or more items, means that any one of the listed items can be employed by itself or any combination of two or more of the listed items can be employed. For example, if a composition is described as containing or excluding components A, B, and/or C, the composition can contain or exclude A alone; B alone; C alone; A and B in combination; A and C in combination; B and C in combination; or A, B, and C in combination.

The present description also uses numerical ranges to quantify certain parameters relating to various embodiments of the invention. It should be understood that when numerical ranges are provided, such ranges are to be construed as providing literal support for claim limitations that only recite the lower value of the range as well as claim limitations that only recite the upper value of the range. For example, a disclosed numerical range of about 10 to about 100 provides literal support for a claim reciting “greater than about 10” (with no upper bounds) and a claim reciting “less than about 100” (with no lower bounds).

### EXAMPLES

The following examples set forth methods in accordance with the invention. It is to be understood, however, that these examples are provided by way of illustration and nothing therein should be taken as a limitation upon the overall scope of the invention.

### Example 1

### Bonding Material 1

A bonding composition was prepared by adding 80 grams of PEAM-645 (Designer Molecules, San Diego, Calif.) and 20 grams of PGME (FUJIFILM Ultra Pure Solutions, Inc. Carrollton, Tex.) to a plastic bottle, followed by mixing on a stir wheel. The solution was filtered with a 0.1-μm end point filter (Meissner, Camarillo, Calif.) into a plastic bottle.

### Example 2

### Bonding Material 1A

In this Example, 3.3 grams of bis(benzylidene malononitrile) dye (Brewer Science, Rolla, Mo.) were dissolved in 29.6 grams of cyclopentanone (FUJIFILM Ultra Pure Solutions, Inc. Carrollton, Tex.). The dye solution was added to 65.8 grams of PEAM-645 in a plastic bottle. Next, 1.3 grams of dicumyl peroxide were added to the mixture, followed by mixing on a stir wheel. The solution was filtered with a 0.2-μm into a plastic bottle.

### Example 3

### Bonding Material 1B

A bonding composition was prepared by adding 60 grams of PEAM-645 and 40 grams of PGME to a plastic bottle and then mixing on a stir wheel. The solution was filtered with a 0.1-μm end point filter into a plastic bottle.

### Example 4

### Bonding Material 1C

In this preparation procedure, 34.3 grams of PEAM-645, 22.9 grams of PGME, and 42.8 grams of PGMEA (FUJIFILM Ultra Pure Solutions, Inc., Carrolton, Tex.) were added to a plastic bottle and then mixed on a stir wheel. The solution was filtered with a 0.1-μm filter into a plastic bottle.

### Example 5

### Bonding Material 2

In this Example, 50 grams of PEAM-645 and 50 grams of trimethylolpropane triglycidyl ether-4-methoxybenzylidene pyruvic acid solution in PGME (30%, Brewer Science, Rolla, Mo.) were combined and mixed on a stir wheel. The solution was filtered with a 0.2-μm filter into a plastic bottle.

### Example 6

### Bonding Material 2A

A bonding composition was prepared by mixing 21.83 grams of PEAM-645, 21.83 grams of trimethylolpropane triglycidyl ether-4-methoxybenzylidene pyruvic acid solution in PGME (30%), and 56.34 grams of PGME were mixed together and mixed on a stir wheel. The solution was filtered with a 0.2-μm filter into a plastic bottle.

### Example 7

### Bonding Material 3

In this Example, 65.4 grams of PEAM-645 (Designer Molecules, San Diego, Calif.) and 41.9 grams of mesitylene (KMG Electronic Chemicals, Hollister, Calif.) were added to a plastic bottle, followed by mixing on a stir wheel. The solution was filtered with a 0.1-μm end point filter into a plastic bottle.

### Example 8

### Bonding Material 4

In this preparation procedure, 0.1 gram of 9,10-phenanthrenequinone (Sigma Aldrich, St. Louis, Mo.) was dissolved in 4.9 grams of cyclopentanone. The solution was added to 5 grams of PEAM-645 in a plastic bottle, followed by mixing on a stir wheel. The solution was filtered with a 0.2-μm filter into a plastic bottle.

### Example 9

### Processing of the Material from Example 3

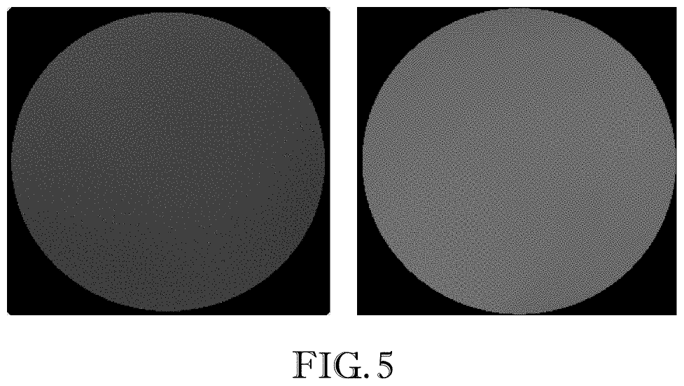

A 5-μm coating of the material from Example 3 was applied to a silicon wafer by spin coating at 1,000 rpm with a ramp of 1,500 rpm/s for 30 seconds. The wafer was then baked at 60° C. for 2 minutes and then at 120° C. for 2 minutes. After baking, a glass wafer was aligned and bonded to the silicon wafer using an EVG bonder at room temperature, with a pressure of 2,000 N, for a time period of 30 seconds. The material was then cured by baking at 200° C. for 10 minutes, giving a void-free bonded wafer pair. FIG. 5 shows the coated silicon wafer (left) and the bonded wafer pair (right).

### Example 10

### Adhesion Testing of the Material from Example 3

The material prepared in Example 3 was tested according to ASTM D4541-17 using a portable pull-off adhesion tester. Adhesion data was collected by averaging three failure values from each set of tests. Table 1 shows the adherence results on various substrates.

TABLE 1
Adhesion properties of the material from Example 3

| | Silicon | Glass | Quartz | SiN | Cu Coated Si | Kapton ® |
|---|---|---|---|---|---|---|
| Product | (psi) | (psi) | (psi) | (psi) | (psi) | (psi) |
| Example 3 | 43 | 34 | 41 | >45 | 10 | 6 |

We claim:

1. A method of forming a microelectronic structure, said method comprising:
providing a substrate having a back surface and a front surface;
applying a composition to said front surface to form a bonding layer, said composition being chosen from:
I. a composition comprising less than about 0.001% by weight of an initiator, based upon the total weight of the composition taken as 100% by weight, and said composition comprising a compound including a moiety having the structure: 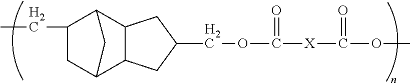
where: each X is independently chosen from substituted or unsubstituted aliphatics, aryls, and heterocyclics; and n is 1 to about 20; or
II. a composition comprising a dye and a compound including a moiety having the structure: 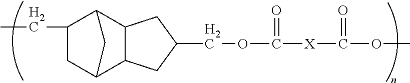
where: each X is independently chosen from substituted or unsubstituted aliphatics, aryls, and heterocyclics; and n is 1 to about 20; and
attaching a die to said bonding layer.

2. The method of claim 1, wherein said composition is composition I, and said composition I consists essentially of said compound dispersed or dissolved in a solvent system.

3. The method of claim 1, wherein said composition is composition II, and said composition II comprises said compound dispersed or dissolved in a solvent system.

4. The method of claim 3, wherein said composition is composition II, and said composition II further comprises an initiator and said compound dispersed or dissolved in a solvent system.

5. The method of claim 1, wherein each X is independently chosen from 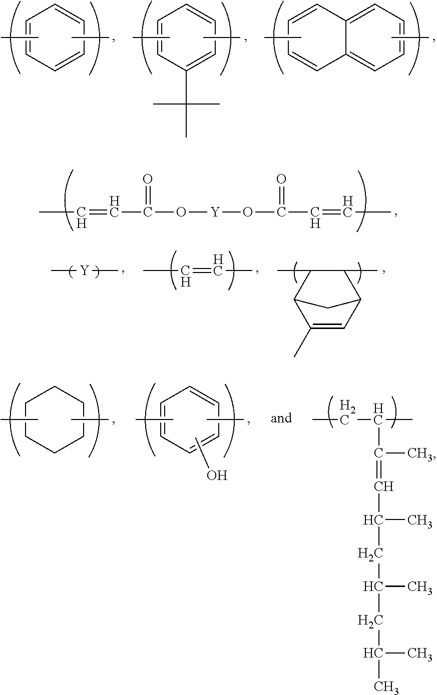
where Y is C₁ to about C₄₅.

6. The method of claim 5, wherein said compound is:

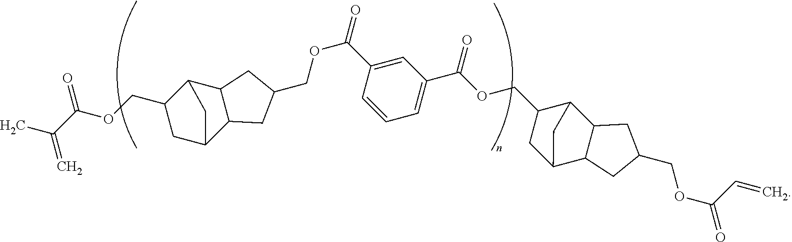

7. A method of forming a microelectronic structure, said method comprising:
providing a substrate having a back surface and a front surface, said substrate optionally including one or more intermediate layers on said front surface;
applying a composition to said front surface, or to said one or more intermediate layers, if present, to form a bonding layer, said composition comprising a compound including a moiety having the structure: 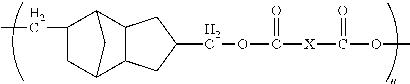
where: each X is independently chosen from substituted or unsubstituted aliphatics, aryls, and heterocyclics; and n is 1 to about 20; and
forming a patterned bonding layer by doing one or both of (A) or (B):
(A) forming a photoresist layer on said bonding layer;
forming a pattern in said photoresist layer; and
transferring said pattern to said bonding layer to form a patterned bonding layer; or
(B) exposing the bonding layer to laser energy so as to remove at least a portion of the bonding layer.

8. The method of claim 7, further comprising placing a die on or in said patterned bonding layer.

9. The method of claim 7, said composition comprising less than about 0.001% by weight of an initiator, based upon the total weight of the composition taken as 100% by weight.

10. The method of claim 7, said composition further comprising a dye.

11. The method of claim 7, wherein said composition comprises said compound dispersed or dissolved in a solvent system.

12. The method of claim 11, wherein said composition consists essentially of said compound dispersed or dissolved in a solvent system.

13. The method of claim 11, wherein said composition further comprises an initiator.

14. The method of claim 7, wherein each X is independently chosen from 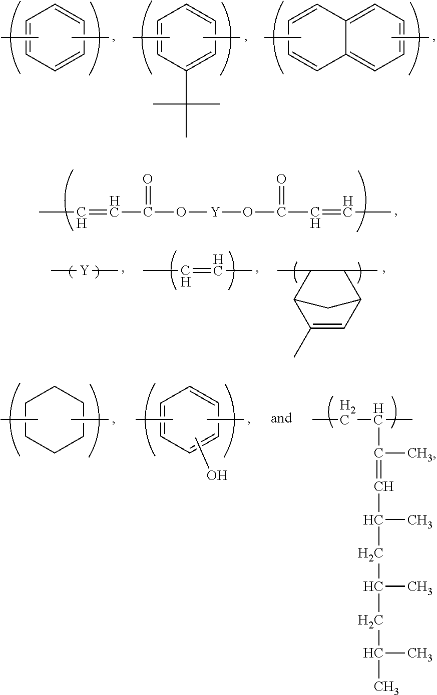
where Y is C₁ to about C₄₅.

15. The method of claim 14, wherein said compound is:

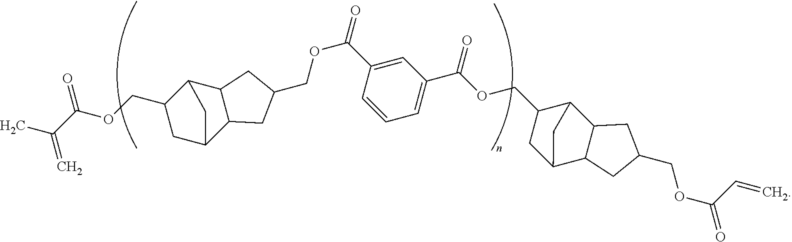

16. A temporary bonding method comprising:
providing a stack comprising:
a first substrate having a back surface and a front surface, said substrate optionally including one or more intermediate layers on said front surface;
a bonding layer on said front surface, or on said one or more intermediate layers, if present, said bonding layer being formed from a composition comprising a dye and a compound including a moiety having the structure: 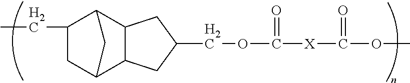
where: each X is independently chosen from substituted or unsubstituted aliphatics, aryls, and heterocyclics; and n is 1 to about 20; and
a second substrate having a first surface, said bonding layer being on said first surface; and
exposing said bonding layer to laser energy so as to facilitate separation of said first and second substrates.

17. The method of claim 16, said composition comprising less than about 0.001% by weight of an initiator, based upon the total weight of the composition taken as 100% by weight.

18. The method of claim 16, wherein said composition consists essentially of said compound and dye dispersed or dissolved in a solvent system.

19. The method of claim 16, wherein said composition further comprises an initiator.

20. The method of claim 16, wherein each X is independently chosen from 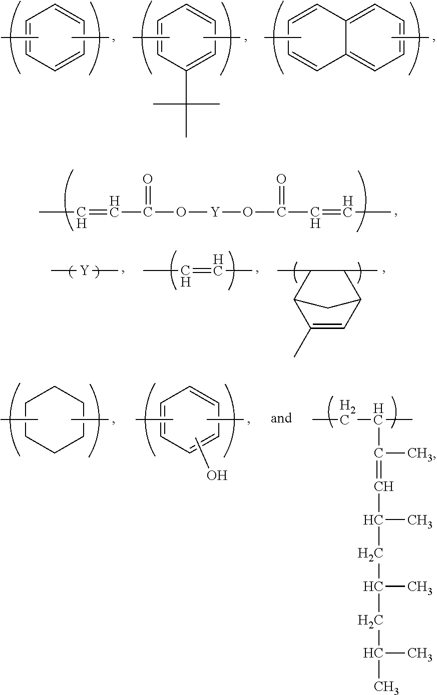
where Y is C₁ to about C₄₅.

21. The method of claim 20, wherein said compound is:

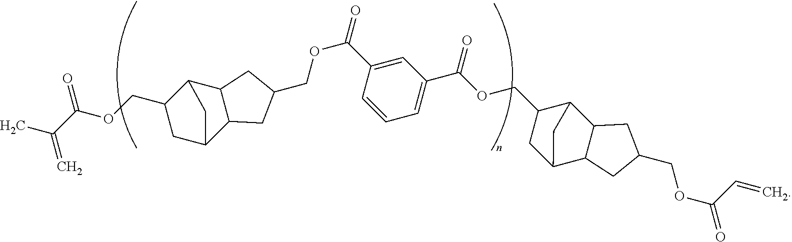

22. A composition comprising a compound dispersed or dissolved in a solvent system, said compound including a moiety having the structure: 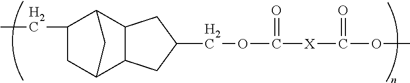
where: each X is independently chosen from substituted or unsubstituted aliphatics, aryls, and heterocyclics; and n is 1 to about 20, said composition further comprising one or both of the following:
(a) a dye; or
(b) less than about 0.001% by weight of an initiator, based on the total weight of the composition being taken as 100% by weight.

23. The composition of claim 22, wherein said composition comprises (b) but not (a), and said composition consists essentially of said compound dissolved or dispersed in said solvent system.

24. The composition of claim 22, wherein said composition comprises (a), and said composition consists essentially of said dye and said compound dissolved or dispersed in said solvent system.

25. The composition of claim 22, wherein said composition comprises (a) but not (b), and said composition further comprises at least about 0.1% by weight of an initiator, based upon the total weight of the composition taken as 100% by weight.

26. The composition of claim 22, wherein each X is independently chosen from 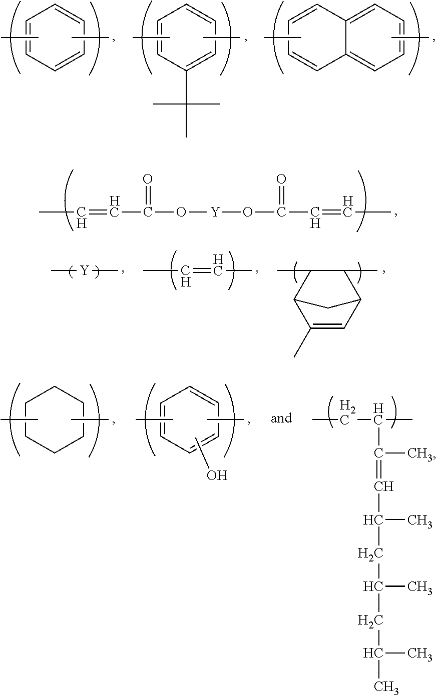
where Y is C₁ to about C₄₅.

27. The composition of claim 26, wherein said compound is: [chemical structure]
